(19) United States
(12) Patent Application Publication
(10) Pub. No.: US 2026/0148762 A1
(43) Pub. Date: May 28, 2026

(54) MEMORY

(71) Applicant: CXMT Corporation, Hefei (CN)

(72) Inventor: Qiyao ZHANG, Hefei (CN)

(21) Appl. No.: 19/428,343

(22) Filed: Dec. 22, 2025

Related U.S. Application Data
(63) Continuation of application No. PCT/CN2025/132850, filed on Nov. 5, 2025.

(30) Foreign Application Priority Data
Nov. 28, 2024 (CN) 202411734754.X

(51) Int. Cl. G11C 11/408; G11C 5/06; H10B 12/00; H10B 80/00; H10D 80/30

(52) U.S. Cl. CPC G11C 11/4085; G11C 5/063; H10B 12/482; H10B 12/488; H10B 80/00; H10D 80/30

(57) ABSTRACT

Embodiments of this application relate to the field of memories, and provide a memory, including a first chip and a second chip that are stacked in a first direction. Multiple memory cells are formed on the first chip, and each of the memory cells is driven by a corresponding local word line. A peripheral circuit is formed on the second chip. Multiple local word line gating circuits are further formed on the first chip, and each of the local word line gating circuits is configured to gate a corresponding local word line.

### CROSS REFERENCE TO RELATED APPLICATIONS

This is a continuation of International Patent Application No. PCT/CN2025/132850 filed on Nov. 5, 2025, which claims priority to Chinese Patent Application No. 202411734754.X, filed on Nov. 28, 2024. The disclosure of these applications is hereby incorporated by reference in their entireties.

### BACKGROUND

A conventional memory chip is prepared based on a two-dimensional plane, with memory cells arranged on a single plane. However, as the demand for a memory with a higher capacity and a smaller size continues to grow, a traditional two-dimensional planar memory technology faces physical and performance limitations.

To solve these problems, a three-dimensional memory technology emerges. The three-dimensional memory technology achieves a higher memory density by stacking multiple layers of memory cells in the vertical direction. This stacked structure can significantly increase a memory capacity of a memory chip, while maintaining the size of the chip relatively small. In addition, a three-dimensional memory also adopts an advanced manufacturing process and material to improve data transmission speed and energy efficiency.

In an existing three-dimensional memory, all memory cells are disposed on one chip, and all circuit structures are disposed on the other chip. However, this design causes area waste due to a requirement of the memory cell for a driving capability.

### SUMMARY

The present disclosure relates to the field of semiconductor technologies, and in particular, to a memory, so that the area of each chip in a three-dimensional memory can be fully utilized to improve a degree of integration.

According to some embodiments of this application, an aspect of the embodiments of this application provides a memory, including a first chip and a second chip that are stacked in a first direction. Multiple memory cells are formed on the first chip, and each of the memory cells is driven by a corresponding local word line. A peripheral circuit is formed on the second chip. Multiple local word line gating circuits are further formed on the first chip, and each of the local word line gating circuits is configured to gate a corresponding local word line.

In some embodiments, the memory cell includes a gating transistor, and a part of the local word line serves as the gate of the gating transistor.

In some embodiments, multiple memory layers stacked in the first direction are disposed on the first chip, and each of the memory layers is provided with multiple memory array tiles. The multiple memory array tiles include a first memory array tile and a second memory array tile that are adjacent to each other in a second direction, and the multiple local word line gating circuits are disposed between the first memory array tile and the second memory array tile. The second direction is perpendicular to the first direction.

In some embodiments, the local word line gating circuit includes a first transistor and a second transistor. The gate of the first transistor is electrically connected to the gate of the second transistor, and the drain of the first transistor and the drain of the second transistor are electrically connected to the local word line. The source of the first transistor is configured to receive a first selection signal, and the source of the second transistor is configured to receive a first power signal.

In some embodiments, each of the memory array tiles includes multiple memory cells arranged in an array in the second direction and a third direction. Gates of a column of memory cells arranged in the second direction share one local word line. Sources of first transistors of the multiple local word line gating circuits between the first memory array tile and the second memory array tile are electrically connected. The third direction is perpendicular to the first direction, and is perpendicular to the second direction.

In some embodiments, the sources of the first transistors of the multiple local word line gating circuits between the first memory array tile and the second memory array tile are connected by means of a first winding structure. Multiple staircases are further formed between the first memory array tile and the second memory array tile. A first winding structure of each memory layer is electrically connected to one staircase, and first winding structures of different memory layers are electrically connected to different staircases.

In some embodiments, each of the memory array tiles includes the multiple memory cells arranged in an array in the second direction and the third direction. The gates of the column of memory cells arranged in the second direction share one local word line. Gates of the first transistors of the multiple local word line gating circuits between the first memory array tile and the second memory array tile are electrically connected, and are configured to receive a second selection signal. The third direction is perpendicular to the first direction, and is perpendicular to the second direction.

In some embodiments, the gates of the first transistors of the multiple local word line gating circuits between the first memory array tile and the second memory array tile are connected by means of a second winding structure. The multiple staircases are further formed between the first memory array tile and the second memory array tile. A second winding structure of each memory layer is electrically connected to one staircase, and second winding structures of different memory layers are electrically connected to different staircases.

In some embodiments, the multiple memory array tiles further include a third memory array tile and a fourth memory array tile. The first memory array tile, multiple local word line gating circuits, the second memory array tile, the third memory array tile, multiple local word line gating circuits, and the fourth memory array tile are arranged in sequence in the second direction.

In some embodiments, each memory array tile includes multiple memory cells arranged in an array in the second direction and the third direction. The gates of the column of memory cells arranged in the second direction share one local word line. Each row of memory cells in two adjacent columns of memory cells in the third direction share one local bit line. Multiple local bit lines of a row of memory cells arranged in the third direction are connected to a same common bit line. The third direction is perpendicular to the first direction, and is perpendicular to the second direction.

The memory provided in the embodiments of this application has at least the following advantages.

The memory includes the first chip and the second chip that are stacked. The multiple memory cells are formed on the first chip, and the peripheral circuit is formed on the second chip. The multiple local word line gating circuits are further formed on the first chip, and each of the local word line gating circuits is configured to gate a corresponding local word line. The local word line gating circuits are disposed on a memory cell chip, so as to implement driving of a memory cell local word line on the memory cell chip, thereby reducing the area of a peripheral circuit chip. This makes the arrangement of a circuit structure of the peripheral circuit chip more proper, thereby improving a degree of integration. In addition, due to a specific circuit design, position, and connection relationship design of the local word line gating circuit, quantities of staircases and transistors of local word line gating circuits are decreased while ensuring correct selection of a local word line, thereby improving area utilization on the memory cell chip.

### BRIEF DESCRIPTION OF DRAWINGS

One or more embodiments are exemplified with figures in the accompanying drawings corresponding to the one or more embodiments. These example descriptions are not intended to limit the embodiments, and unless specifically stated, no scale limitations are constituted by the figures in the accompanying drawings.

FIG. 1 provides a schematic diagram of structural arrangement of two chips in a three-dimensional memory;

FIG. 2 is a schematic structural diagram of a memory according to an embodiment of the present disclosure;

FIG. 3 is a schematic layout diagram of a partial structure of a first chip according to an embodiment of the present disclosure;

FIG. 4 is an enlarged detail diagram of a single local word line gating circuit in FIG. 3;

FIG. 5 is a three-dimensional schematic diagram of a local word line gating circuit in FIG. 3;

FIG. 6 is another schematic layout diagram of a partial structure of a first chip according to an embodiment of the present disclosure;

FIG. 7 is an enlarged detail diagram of a single local word line gating circuit in FIG. 6;

FIG. 8 is a three-dimensional schematic diagram of a local word line gating circuit in FIG. 6; and

FIG. 9 is a schematic diagram of structural arrangement of two chips in a three-dimensional memory according to an embodiment of the present disclosure.

### DESCRIPTION OF EMBODIMENTS

The following describes example embodiments of the present disclosure in detail with reference to the accompanying drawings, so that those skilled in the art can readily practice the present disclosure. As will be recognized by a person skilled in the art, the described embodiments may be modified in various manners, and none of these modifications departs from the spirit or scope of the present disclosure. For example, the example embodiments provided herein are considered to be implemented in combination with one another in whole or in part. Specifically, an element described in a specific example embodiment may be understood as a description related to another example embodiment, even if not described in another example embodiment, unless opposite or contradictory descriptions are provided therein.

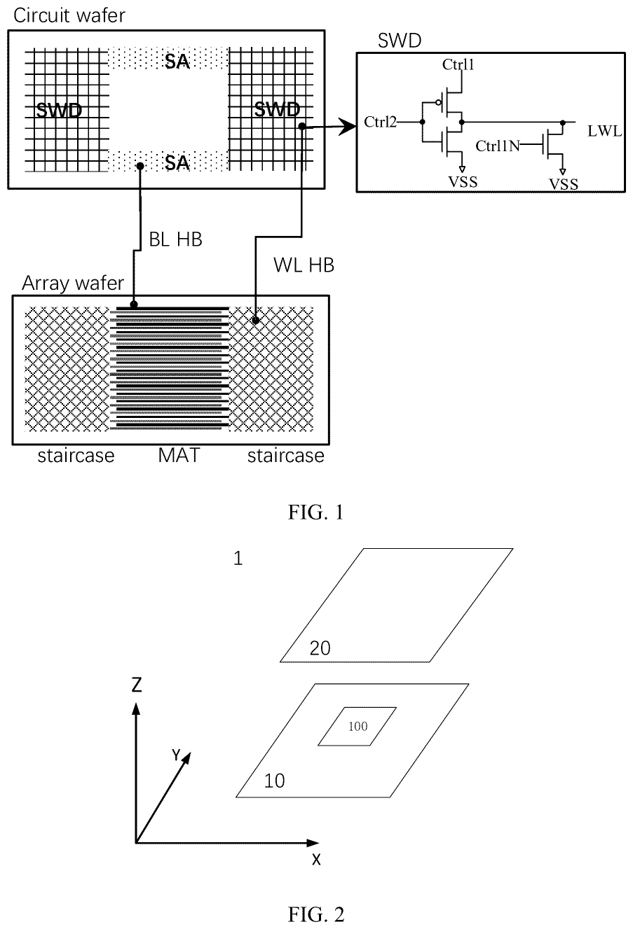

FIG. 1 provides a schematic diagram of structural arrangement of two chips in a three-dimensional memory. It may be learned from the background that, as shown in FIG. 1, in a three-dimensional memory, a memory cell is disposed on one chip (shown as Array wafer in FIG. 1), and a peripheral circuit is disposed on the other chip (shown as Circuit wafer in FIG. 1). The memory cell needs to be driven by a sub word line driver (SWD), and data read from the memory cell needs to be amplified by a sense amplifier (Sense Amplifier, SA) before output. As such, the sense amplifier and the sub word line driver need to be disposed directly above a memory array tile (shown as MAT in FIG. 1) and a staircase (shown as staircase in FIG. 1), and then electrical leading out of a bit line and a word line is achieved through bit line hybrid bonding (shown as BL HB in FIG. 1) and word line hybrid bonding (shown as WL HB in FIG. 1). The disposition of this structure causes a waste area (a blank area between an SA and an SA in FIG. 1) in a peripheral circuit chip, so that utilization of the peripheral circuit chip is not high. In addition, the sub word line driver adopts a conventional structure of three transistors to drive a local word line, and occupies a relatively large area of the chip.

Embodiments of this application provide a memory, where the memory includes a first chip and a second chip that are stacked. Multiple memory cells are formed on the first chip, and a peripheral circuit is formed on the second chip. Multiple local word line gating circuits are further formed on the first chip, and each of the local word line gating circuits is configured to gate a corresponding local word line. The local word line gating circuits are disposed on a memory cell chip, so as to implement driving of a memory cell local word line on the memory cell chip, thereby reducing the area of a peripheral circuit chip. This makes the arrangement of a circuit structure of the peripheral circuit chip more proper, thereby improving a degree of integration. In addition, due to a specific circuit design, position, and connection relationship design of the local word line gating circuit, quantities of staircases and transistors of local word line gating circuits are decreased while ensuring correct selection of a local word line, thereby improving area utilization on the memory cell chip.

The embodiments of this application are described in more detail below with reference to the accompanying drawings.

FIG. 2 is a schematic structural diagram of a memory according to an embodiment of the present disclosure. Referring to FIG. 2, a memory 1 is provided, including a first chip 10 and a second chip 20 that are stacked in a first direction Z.

Multiple memory cells are formed on the first chip 10, and each of the memory cells is driven by a corresponding local word line.

A peripheral circuit is formed on the second chip 20.

Multiple local word line gating circuits 100 are further formed on the first chip 10, and each of the local word line gating circuits 100 is configured to gate a corresponding local word line.

The multiple memory cells on the first chip 10 may be arranged in an array. Each of the memory cells arranged in an array is connected to one word line and one bit line, and is driven by a corresponding word line and a corresponding bit line. In the field of three-dimensional memories, a word line may be classified as a common word line (common word line, CWL) and a local word line (local word line, LWL). One common word line is connected to each of multiple local word lines by means of multiple local word line selection transistors. A bit line may be classified as a common bit line (common bit line, CBL) and a local bit line (local bit line, LBL). One common bit line may be connected to multiple local bit lines by means of multiple local bit line selection transistors. In this technology, each memory cell is connected to one local word line and one local bit line, and is driven by the corresponding local word line and the corresponding local bit line, so that the memory cell is enabled.

The peripheral circuit is formed on the second chip 20, so that a memory array is formed on the first chip, and a CMOS circuit is formed on the second chip. The peripheral circuit includes CMOS logic circuits such as a row decoder, a column decoder, a sense amplifier, a data input/output circuit, a clock generation circuit, and a delay-locked loop.

The multiple local word line gating circuits 100 are further formed on the first chip 10, and each of the local word line gating circuits 100 is configured to gate a corresponding local word line, so as to drive the corresponding local word line to enable a memory cell on the corresponding local word line.

In some embodiments, one local word line gating circuit 100 is configured to drive a local word line connected to the local word line gating circuit 100. In some other embodiments, one local word line gating circuit 100 may also be connected to two local word lines or four local word lines, so as to drive the two local word lines or the four local word lines, thereby implementing reuse of the local word line gating circuit and reducing the area of the local word line gating circuit. In another embodiment, the local word line gating circuit may further drive another quantity of local word lines. This is not limited in this application.

In some embodiments, in response to the local word line gating circuits 100 being formed on the first chip, the row decoder may also be partially formed on the first chip 10, so as to reduce a path of an input signal of the local word line gating circuit and improve a driving capability of the local word line gating circuit.

In this way, the local word line gating circuits are disposed on the first chip provided with the memory cell array, so that each of the local word line gating circuits is closer to a memory cell to be driven by the local word line gating circuit, which can improve the driving capability of the local word line gating circuit. In addition, because the local word line gating circuit is disposed on the first chip, a corresponding position on the second chip is freed up. The freed up space may be used for disposing another peripheral circuit, thereby reducing a chip area and improving the degree of integration.

In some embodiments, the memory may be a dynamic random access memory (DRAM). Correspondingly, the memory cell may include one gating transistor and one capacitor. In some other embodiments, the memory cell of the DRAM memory may alternatively have a structure of 2T0C (that is, a two-transistor zero-capacitor DRAM), or 1T0C (that is, a one-transistor zero-capacitor DRAM). The following description uses a conventional 1T1C structure as an example, that is, a DRAM memory cell includes one transistor and one capacitor.

The memory cell may include a gating transistor, and a part of a local word line may be used as the gate of the gating transistor. For example, in a DRAM memory with a 1T1C memory cell, the gating transistor is 1T in the 1T1C. The 1T may be a MOS transistor, and the gate of the MOS transistor is driven by a local word line. During process preparation, one local word line may be connected to multiple memory cells. In other words, one local word line serves as gates of the multiple memory cells, or a part of one local word line serves as the gate of one gating transistor.

In this way, a corresponding local word line may be gated by means of a local word line driver circuit, so as to gate a corresponding memory cell to perform data read/write.

In some embodiments, multiple memory layers stacked in the first direction Z may be disposed on the first chip 10. Each of the memory layers is provided with multiple memory array tiles (memory array tile, MAT), and the multiple memory array tiles are arranged in a second direction Y. The multiple memory array tiles include a first memory array tile MAT1 and a second memory array tile MAT2 that are adjacent to each other in the second direction Y, and the multiple local word line gating circuits 100 are disposed between the first memory array tile MAT1 and the second memory array tile MAT2. The second direction Y is perpendicular to the first direction Z.

The local word line gating circuits are disposed between the first memory array tile and the second memory array tile, so that each of the local word line gating circuits is closer to a local word line, resulting in a shorter path and lower loss of the driving capability along the path. In addition, the first memory array tile and the second memory array tile can share the local word line gating circuit, thereby reducing a circuit area.

In addition, because a driving function of the sub word line driver SWD is implemented by the local word line gating circuit, only one corresponding local word line LWL is driven each time. Compared with a structure in the prior art, this structure reduces loads of a resistor and a capacitor. As such, more memory cells can be connected to one local word line LWL.

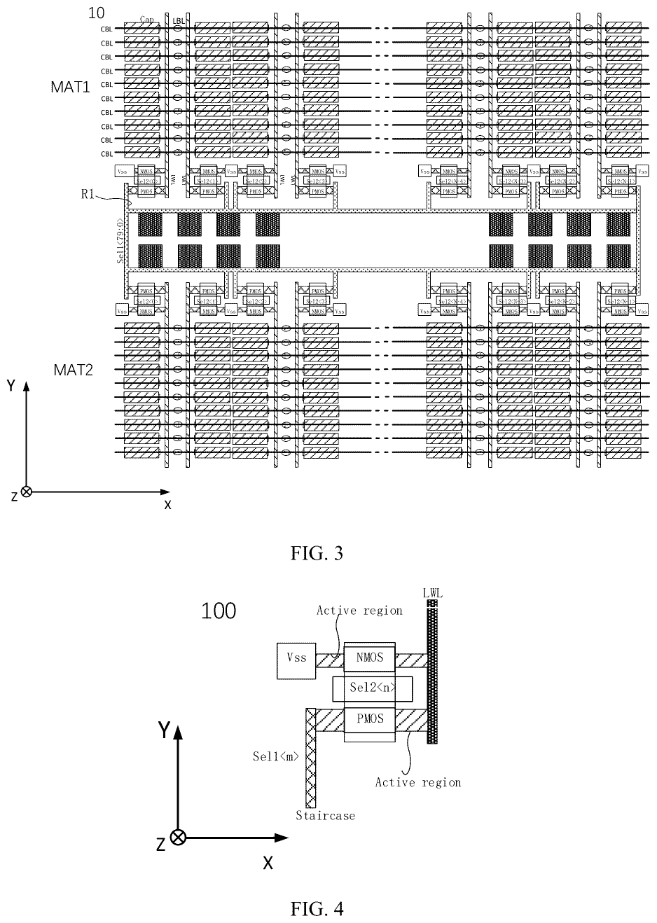

FIG. 3 is a schematic layout diagram of a partial structure of a first chip according to an embodiment of the present disclosure. FIG. 3 illustrates layouts and specific structures of a first memory array tile MAT1, multiple local word line gating circuits 100, and a second memory array tile MAT2. FIG. 3 is a top view. FIG. 4 is an enlarged detail diagram of a single local word line gating circuit in FIG. 3.

Referring to FIG. 4, a local word line gating circuit 100 includes a first transistor (shown as a PMOS) and a second transistor (shown as an NMOS). Gates of the first transistor and the second transistor are electrically connected, and receive a second selection signal Sel2. Because there are multiple local word lines and multiple local word line gating circuits on the first chip, correspondingly, multiple second selection signals are also provided. For one of the local word line gating circuits and a second selection signal received by the local word line gating circuit, Sel2<n> is used as an example. The drain of the first transistor and the drain of the second transistor are electrically connected to a local word line LWL. As shown in FIG. 4, a drain region of the first transistor and a drain region of the second transistor may be directly connected to a corresponding local word line. The source of the first transistor (PMOS) receives a first selection signal Sel1. Because there are multiple local word lines and multiple local word line gating circuits on the first chip, correspondingly, multiple first selection signals are also provided. For one of the local word line gating circuits and a first selection signal received by the local word line gating circuit, Sel1<m> is used as an example. Both m and n are positive integers. The source of the second transistor (NMOS) receives a first power signal Vss. For the NMOS, the first power signal is a low-level signal, for example, may be a ground level. The first power signal may alternatively be a negative voltage, for example, −0.2V. For different process nodes and products, the negative voltage may be another value. In FIG. 4, the gate of the NMOS transistor is electrically connected to the gate of the PMOS transistor, and below the gates receiving the second selection signal Sel2<n> are active regions (Active region) of the NMOS transistor and the PMOS transistor.

The first selection signal and the second selection signal may be generated by the row decoder through address decoding. The row decoder may obtain the first selection signal and the second selection signal by decoding an address. An address of one local word line (or, as described above, addresses of two or four local word lines in another embodiment) by means of the first selection signal and the second selection signal, so that a corresponding local word line is activated in the memory array. The first selection signal may be a phase selection signal (also called phase selector), and the second selection signal may be a group selection signal (also called group selector). The sub word line driver selects a corresponding local word line by receiving the first selection signal and the second selection signal obtained through decoding by the row decoder.

Because the local word line gating circuits are disposed on the first chip, a path between the local word line gating circuits and the memory cells is relatively short, and a loss of the driving capability along the path is relatively low. As such, each of the local word line gating circuits may be provided with only two transistors. Compared with a structure of three transistors or 2.5 transistors in the prior art, this structure further reduces an area.

In some embodiments, each of the memory array tiles includes multiple memory cells arranged in an array in the second direction Y and a third direction X, and gates of a column of memory cells arranged in the second direction Y share one local word line.

Sources of first transistors PMOS of the multiple local word line gating circuits between the first memory array tile MAT1 and the second memory array tile MAT2 are electrically connected.

The third direction X is perpendicular to the first direction Z, and is perpendicular to the second direction Y.

Still referring to FIG. 3, the first memory array tile MAT1 is used as an example. The MAT1 includes multiple memory cells arranged in an array in the second direction Y and the third direction X. Each of the memory cells includes one capacitor Cap and one gating transistor (not shown in FIG. 3). One terminal of the gating transistor is connected to a local bit line LBL, and the other terminal of the gating transistor is connected to the capacitor Cap. A control terminal of the gating transistor is connected to a local word line LWL. The gates of the column of memory cells arranged in the second direction Y share one local word line. In other words, a local word line LWL extending in the second direction Y serves as gates of gating transistors of multiple memory cells.

The sources of the first transistors PMOS of the multiple local word line gating circuits between the first memory array tile MAT1 and the second memory array tile MAT2 are electrically connected, and receive the same first selection signal Sel1<m>. In the example of FIG. 3, sources of first transistors PMOS of all local word line gating circuits between the first memory array tile MAT1 and the second memory array tile MAT2 are electrically connected by means of a first winding structure R1. In other words, two adjacent memory array tiles MAT1 and MAT2 at one memory layer receive the same first selection signal Sel1<m> Two adjacent MATs at one memory layer may be selected by means of one first selection signal Sel1<m>.

Still referring to FIG. 3, adjacent local word lines LWL in the same memory array tile MAT1 are connected to different local word line gating circuits, and different local word line gating circuits receive different second selection signals Sel2<n>. For example, in FIG. 3, in the third direction X, the second selection signals Sel2<n> received by the different local word line gating circuits are sequentially Sel2<0>, Sel2<1>, Sel2<2>, Sel2<3>, . . . , Sel2<N−4>, Sel2<N−3>, Sel2<N−2>, and Sel2<N−1>.

In this way, at the same memory layer, the first memory array tile and second memory array tile that are adjacent to each other may enable all local word line gating circuits to share the same first selection signal by means of the first winding structure, and implement enabling and disabling functions of a local word line LWL by means of different second selection signals of the local word line gating circuits. Specifically, enabling and disabling of the first transistor and the second transistor are controlled by means of the second selection signal to determine a specific group of local word lines LWL to be connected to a corresponding first selection signal. Then, a specific layer at which a local word line LWL is to be enabled is determined by selecting to enable a first selection signal at a specific layer. In this case, a local word line LWL at another layer is in a disabled state. A local word line LWL that is not enabled by the second selection signal is connected to a low-level voltage Vss, so that the local word line LWL is in a disabled state. In this case, local bit lines LBL on different local word lines LWL may be connected to the same common bit line CBL by means of a bit line gating transistor, and share one sense amplifier on the second chip.

In this way, the enabling and disabling functions of a local word line LWL are implemented by means of two transistors (that is, the first transistor PMOS and the second transistor NMOS) and two selection signals (that is, the first selection signal and the second selection signal), so as to implement gating.

In addition, for the first memory array tile MAT1 and the second memory array tile MAT2 that are adjacent to each other, second selection signals at corresponding positions are the same. In this way, one local word line address can simultaneously enable one local word line LWL in the first memory array tile MAT1 and one local word line LWL in the second memory array tile MAT2. In a case of a same quantity of addresses, a memory capacity and an amount of data read/written at one time can be increased.

Still referring to FIG. 3, multiple staircases are further formed between the first memory array tile MAT1 and the second memory array tile MAT2. A first winding structure R1 of each memory layer is electrically connected to one staircase, so that the first winding structure R1 of each memory layer is led out for electrical connection. First winding structures R1 of different memory layers are electrically connected to different staircases.

Specifically, the staircase is disposed on an inner side of the first winding structure R1, and each of the staircases is connected to a first winding structure R1 corresponding to each memory layer. There are 80 memory layers in the embodiment in FIG. 3. Correspondingly, 80 staircases (not completely shown in FIG. 3) are provided. Multiple local word line gating circuits at each memory layer are connected to a corresponding first selection signal Sel1<79:0> by means of a first winding structure R1. Each memory layer is led out by means of a corresponding staircase. Then, each memory layer is led out on the top of the first chip by means of an upper metal routing structure on the top of the first chip, and is electrically connected to the second chip through hybrid bonding.

In this way, first selection signals at different layers can be controlled by means of the staircases to determine a specific layer at which a local word line LWL is to be enabled, and a local word line LWL at another layer is in a disabled state.

FIG. 3 is a top view, and therefore shows multiple staircases. One memory layer is electrically connected to only one staircase.

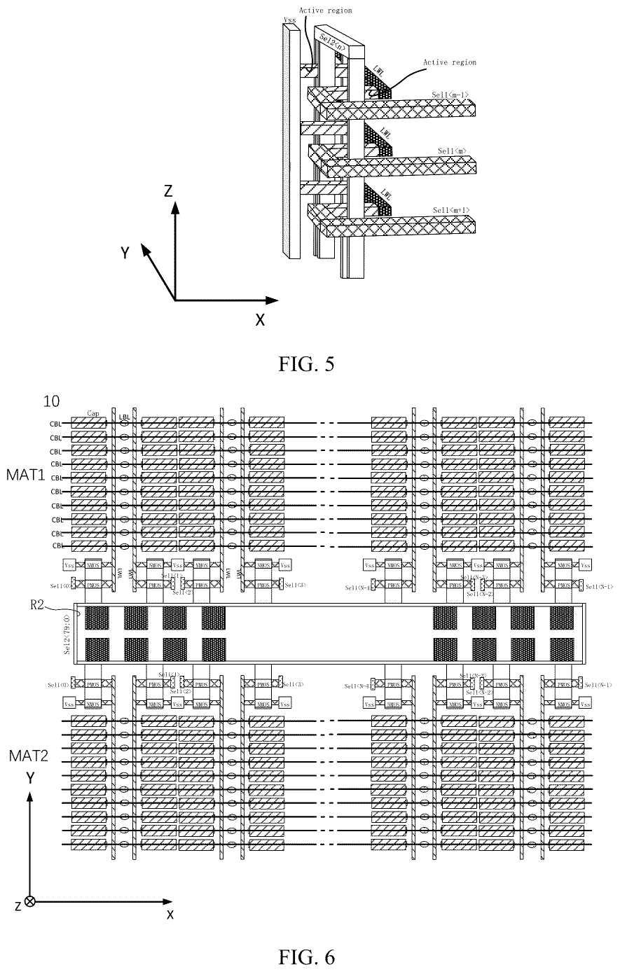

FIG. 5 is a three-dimensional schematic diagram of the local word line gating circuit corresponding to FIG. 3 and FIG. 4. Referring to FIG. 5, the local word line gating circuits are located at different memory layers. For example, for the m^{th} layer, the source of the first transistor of the local word line gating circuit is connected to the first winding structure, and the first winding structure receives the corresponding first selection signal Sel1<m>, and the local word line gating circuit is gated by the corresponding first selection signal Sel1<m>. Multiple memory layers may be connected to a common conductor structure, so that the source of the second transistor (NMOS) receives the first power supply voltage signal Vss. Local word line gating circuits corresponding to different layers may be connected to the same conductor structure, so that the gate of the first transistor (PMOS) and the gate of the second transistor (NMOS) can receive the same second selection signal Sel2<n>. In FIG. 5, conductor structures for applying a gate voltage to active regions are located on two sides of the active regions in the second direction Y.

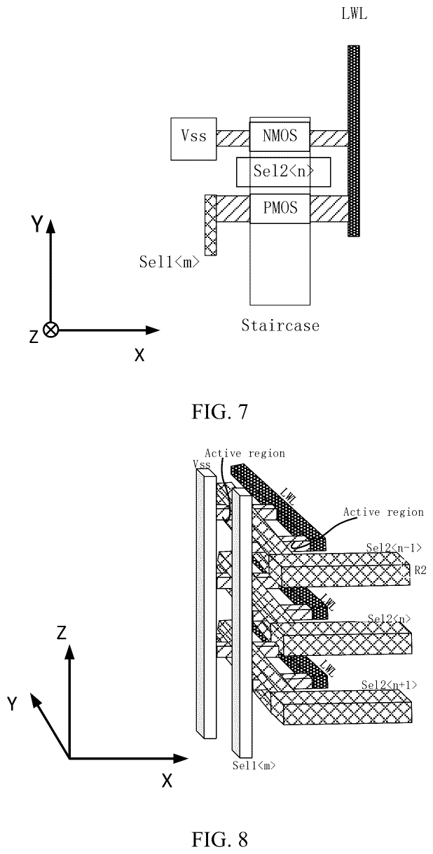

FIG. 6 to FIG. 8 provide an implementation of a local word line gating circuit according to another embodiment of the present disclosure. Content that is the same as that of embodiments in FIG. 3 to FIG. 5 is omitted herein for simplicity. FIG. 6 is a schematic layout diagram of a partial structure of a first chip according to an embodiment of the present disclosure. FIG. 6 illustrates layouts, specific structures, and connection relationships of the first memory array tile MAT1, the multiple local word line gating circuits 100, and the second memory array tile MAT2. FIG. 6 is a top view. FIG. 7 is an enlarged detail diagram of a single local word line gating circuit in FIG. 6. FIG. 8 is a three-dimensional schematic diagram of a lead-out relationship of local word line gating circuits at multiple memory layers.

Referring to FIG. 6 to FIG. 7, each memory array tile includes multiple memory cells arranged in an array in the second direction Y and the third direction X. Gates of a column of memory cells arranged in the second direction Y share one local word line LWL. Gates of first transistors PMOS of multiple local word line gating circuits between the first memory array tile MAT1 and the second memory array tile MAT2 are electrically connected, and are configured to receive a second selection signal Sel2<n>. The third direction X is perpendicular to a first direction Z, and is perpendicular to the second direction Y. The gates of the first transistors of the multiple local word line gating circuits between the first memory array tile MAT1 and the second memory array tile MAT2 are connected by means of a second winding structure R2. Multiple staircases are further formed between the first memory array tile MAT1 and the second memory array tile MAT2. A second winding structure of each memory layer is electrically connected to one staircase, and second winding structures of different memory layers are electrically connected to different staircases.

Specifically, referring to FIG. 7, different from FIG. 4, gates that are connected to each other and that are of two transistors of a local word line gating circuit are led out and connected to a staircase. For a more specific structure, refer to FIG. 6.

Gates connected to both the first transistors PMOS and the second transistors NMOS that are of the multiple local word line gating circuits between the first memory array tile MAT1 and the second memory array tile MAT2 are electrically connected to each other, and receive the same second selection signal Sel2<n>. In the example of FIG. 6, gates of first transistors PMOS of all local word line gating circuits between the first memory array tile MAT1 and the second memory array tile MAT2 are electrically connected by means of a second winding structure R2. In other words, two adjacent memory array tiles MAT1 and MAT2 at one memory layer receive the same second selection signal Sel2<n> Two adjacent MATs at one memory layer may be selected by means of one second selection signal Sel2<n>.

Still referring to FIG. 6, adjacent local word lines LWL in the same memory array tile MAT1 are connected to different local word line gating circuits, and different local word line gating circuits receive different first selection signals Sel1<m>. For example, in FIG. 6, in the third direction X, the first selection signals Sel1<m> received by the different local word line gating circuits are sequentially Sel1<0>, Sel1<1>, Sel1<2>, Sel1<3>, . . . , Sel1<N−4>, Sel1<N−3>, Sel1<N−2>, and Sel1<N−1>.

In this way, at the same memory layer, the first memory array tile and the second memory array tile that are adjacent to each other may enable all local word line gating circuits to share the same second selection signal by means of the second winding structure R2, and implement enabling and disabling functions of a local word line LWL by means of different first selection signals of the local word line gating circuits. Specifically, enabling and disabling of the first transistor and the second transistor are controlled by means of the second selection signal to determine a specific layer at which a local word line LWL is to be connected to a corresponding first selection signal. Then, a specific group of local word lines LWL to be enabled are determined by means of a vertically controlled first selection signal. In this case, a local word line LWL at another layer is in a disabled state. A local word line LWL that is not enabled by the first selection signal is connected to a low-level voltage Vss, so that the local word line LWL is in a disabled state. In this case, local bit lines LBL on different local word lines LWL may be connected to the same common bit line CBL by means of a bit line gating transistor, and share one sense amplifier on the second chip.

In this way, the enabling and disabling functions of a local word line LWL are implemented by means of two transistors (that is, the first transistor PMOS and the second transistor NMOS) and two selection signals (that is, the first selection signal and the second selection signal), so as to implement gating.

In addition, for the first memory array tile MAT1 and the second memory array tile MAT2 that are adjacent to each other, first selection signals at corresponding positions are the same. In this way, one local word line address may simultaneously enable one local word line LWL in the first memory array tile MAT1 and one local word line LWL in the second memory array tile MAT2. In a case of a same quantity of addresses, a memory capacity and an amount of data read/written at one time may be increased.

Still referring to FIG. 6, the staircase is disposed on an inner side of the second winding structure R2, and each staircase is connected to a second winding structure R2 corresponding to each memory layer. There are 80 memory layers in the embodiment in FIG. 6. Correspondingly, 80 staircases (not completely shown in FIG. 6) are provided. Multiple local word line gating circuits at each memory layer are connected to a corresponding second selection signal Sel2<79:0> by means of a second winding structure R2. Each memory layer is led out by means of a corresponding staircase. Then, each memory layer is led out on the top of the first chip by means of an upper metal routing structure on the top of the first chip, and is electrically connected to the second chip through hybrid bonding.

In this way, second selection signals at different layers can be controlled by means of the staircases to determine a specific layer at which a local word line LWL is to be enabled, and a local word line LWL at another layer is in a disabled state.

FIG. 6 is a top view, and therefore shows multiple staircases. One memory layer is electrically connected to only one staircase.

FIG. 8 is a three-dimensional schematic diagram of the local word line gating circuit corresponding to FIG. 6 and FIG. 7. Referring to FIG. 8, the local word line gating circuits are located at different memory layers. For example, for the n^{th} layer, the gate of the first transistor (PMOS) of the local word line gating circuit is connected to the second winding structure, and the second winding structure receives the corresponding second selection signal Sel2<n>, and the local word line gating circuit is gated by the corresponding second selection signal Sel2<n>. Multiple memory layers may be connected to a common conductor structure, so that the source of the second transistor (NMOS) receives the first power supply voltage signal Vss. Local word line gating circuits corresponding to different layers may be connected to the same conductor structure, so that the source of the first transistor (PMOS) can receive the same first selection signal Sel1<m>. In FIG. 8, conductor structures for applying a gate voltage to active regions are located on two sides of the active regions in the first direction Z.

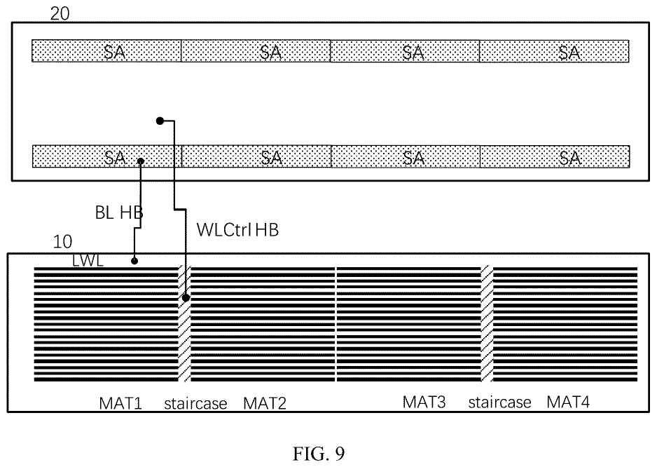

FIG. 9 shows a schematic diagram of structural arrangement of two chips in a three-dimensional memory according to an embodiment of the present disclosure. The embodiments of FIG. 3 and FIG. 6 are enlarged diagrams of the first memory array tile MAT1, the second memory array tile MAT2, and the staircase therebetween in FIG. 9. As shown in FIG. 9, the three-dimensional memory includes a first chip 10, on which a memory cell array and staircases are formed; and a second chip 20, on which sense amplifiers SA and peripheral circuits, such as a row decoder, a column decoder, an input/output circuit, and another circuit structure, are formed. Multiple memory layers are formed on the first chip, and multiple memory array tiles are formed on each of the memory layers. The multiple memory array tiles include a first memory array tile MAT1, a second memory array tile MAT2, a third memory array tile MAT3, and a fourth memory array tile MAT4. The first memory array tile, multiple local word line gating circuits, the second memory array tile, the third memory array tile, multiple local word line gating circuits, and the fourth memory array tile are arranged in sequence in the second direction.

Two adjacent memory array tiles can share one group of local word line gating circuits between the two adjacent memory array tiles by adopting the structure and wiring of the local word line gating circuit as well as the structure and layout of the staircase as described above. In other words, the two memory array tiles can use only one group of local word line gating circuits and staircases (as shown in FIG. 9, no local word line gating circuit or staircase needs to be disposed between the second memory array tile and the third memory array tile), thereby greatly reducing the area of the local word line gating circuit and the area occupied by the staircase. In addition, because two adjacent memory array tiles share a staircase therebetween, a staircase does not need to be specially set for a memory array tile located at an edge of a memory layer, so as to resolve a problem of an edge memory array tile. In addition, as shown in FIG. 9, a position on the second chip originally intended for a sub word line driver (SWD) circuit is freed up and can be used for placing another peripheral circuit.

The present disclosure is not limited thereto, and more than four memory array tiles may be formed on each memory layer. In this embodiment, only four memory array tiles are used as an example. When there are more than four memory array tiles, each two adjacent memory array tiles may share a local word line gating circuit, and all memory array tiles can be driven by means of only half of a quantity of memory array tiles.

Still referring to FIG. 9, bit lines BL on the first chip 10 can be electrically led out through hybrid bonding BL HB after routing in a metal layer, so as to be connected to the sense amplifiers SA on the second chip 20. A word line on the first chip 10 may be electrically led out to the top of the first chip 10 by means of a staircase, and is electrically connected to a peripheral circuit (for example, a row decoder) on the second chip through hybrid bonding WL Ctrl HB on the top of the first chip 10, so as to perform signal driving.

Still referring to FIG. 3 and FIG. 6, each memory array tile includes multiple memory cells arranged in an array in the second direction Y and the third direction X. The gates of the column of memory cells arranged in the second direction Y share one local word line LWL. Each row of memory cells in two adjacent columns of memory cells in the third direction X share one local bit line LBL (indicated by a circle in FIG. 3 and FIG. 6). Multiple local bit lines LBL of a row of memory cells arranged in the third direction X are connected to a same common bit line CBL (indicated by a line segment in FIG. 3 and FIG. 6). The third direction X is perpendicular to the first direction Z, and is perpendicular to the second direction Y.

In this way, use of the local word line LWL, the local bit line LBL, the common bit line CBL, and the common word line CWL can make opening of the bit line and the word line more flexible, and make resistive-capacitive loading (RC loading) smaller.

A person of ordinary skill in the art may understand that the foregoing implementations are specific embodiments for implementing this application. In actual application, various modifications may be made to the forms and details of the implementations without departing from the spirit and scope of this application. Any person skilled in the art may make changes and modifications without departing from the spirit and scope of this application. Therefore, the protection scope of this application shall be subject to the scope defined by the claims.

What is claimed is:

1. A memory, comprising a first chip and a second chip that are stacked in a first direction;
a plurality of memory cells being formed on the first chip, and each of the memory cells being driven by a corresponding local word line;
a peripheral circuit being formed on the second chip; and
a plurality of local word line gating circuits being further formed on the first chip, and each of the local word line gating circuits is configured to gate a corresponding local word line.

2. The memory according to claim 1, wherein the memory cell comprises a gating transistor, and a part of the local word line serves as a gate of the gating transistor.

3. The memory according to claim 1, wherein a plurality of memory layers stacked in the first direction are disposed on the first chip, each of the memory layers is provided with a plurality of memory array tiles, the plurality of memory array tiles comprise a first memory array tile and a second memory array tile that are adjacent to each other in a second direction, the plurality of local word line gating circuits are disposed between the first memory array tile and the second memory array tile, and the second direction is perpendicular to the first direction.

4. The memory according to claim 3, wherein the local word line gating circuit comprises a first transistor and a second transistor; and
a gate of the first transistor is electrically connected to a gate of the second transistor, a drain of the first transistor and a drain of the second transistor are electrically connected to the local word line, a source of the first transistor is configured to receive a first selection signal, and a source of the second transistor is configured to receive a first power signal.

5. The memory according to claim 4, wherein each of the memory array tiles comprises a plurality of memory cells arranged in an array in the second direction and a third direction, and gates of a column of memory cells arranged in the second direction share one local word line;
sources of first transistors of the plurality of local word line gating circuits between the first memory array tile and the second memory array tile are electrically connected; and
the third direction is perpendicular to the first direction, and is perpendicular to the second direction.

6. The memory according to claim 5, wherein the sources of the first transistors of the plurality of local word line gating circuits between the first memory array tile and the second memory array tile are connected by means of a first winding structure; and
a plurality of staircases are further formed between the first memory array tile and the second memory array tile, a first winding structure of each memory layer is electrically connected to one staircase, and first winding structures of different memory layers are electrically connected to different staircases.

7. The memory according to claim 4, wherein each of the memory array tiles comprises a plurality of memory cells arranged in an array in the second direction and a third direction, and gates of a column of memory cells arranged in the second direction share one local word line;
gates of first transistors of the plurality of local word line gating circuits between the first memory array tile and the second memory array tile are electrically connected, and are configured to receive a second selection signal; and
the third direction is perpendicular to the first direction, and is perpendicular to the second direction.

8. The memory according to claim 7, wherein the gates of the first transistors of the plurality of local word line gating circuits between the first memory array tile and the second memory array tile are connected by means of a second winding structure; and
a plurality of staircases are further formed between the first memory array tile and the second memory array tile, a second winding structure of each memory layer is electrically connected to one staircase, and second winding structures of different memory layers are electrically connected to different staircases.

9. The memory according to claim 3, wherein the plurality of memory array tiles further comprise a third memory array tile and a fourth memory array tile, the first memory array tile, a plurality of local word line gating circuits, the second memory array tile, the third memory array tile, a plurality of local word line gating circuits, and the fourth memory array tile are arranged in sequence in the second direction.

10. The memory according to claim 3, wherein each memory array tile comprises a plurality of memory cells arranged in an array in the second direction and a third direction, and gates of a column of memory cells arranged in the second direction share one local word line;
each row of memory cells in two adjacent columns of memory cells in the third direction share one local bit line;
a plurality of local bit lines of a row of memory cells arranged in the third direction are connected to a same common bit line; and
the third direction is perpendicular to the first direction, and is perpendicular to the second direction.
